(19) United States
(12) Patent Application Publication
(10) Pub. No.: US 2024/0429301 A1
(43) Pub. Date: Dec. 26, 2024

(54) PEROVSKITE-BASED FIELD EFFECT TRANSISTOR (FET) DEVICES ENABLED BY EPITAXIAL LATERAL OVERGROWTH

(71) Applicant: Intel Corporation, Santa Clara, CA (US)

(72) Inventors: Rachel A. Steinhardt, Beaverton, OR (US); Dmitri Evgenievich Nikonov, Beaverton, OR (US); Kevin P. O'Brien, Portland, OR (US); John J. Plombon, Portland, OR (US); Tristan A. Tronic, Aloha, OR (US); Ian Alexander Young, Olympia, WA (US); Matthew V. Metz, Portland, OR (US); Marko Radosavljevic, Portland, OR (US); Carly Rogan, North Plains, OR (US); Brandon Holybee, Portland, OR (US); Raseong Kim, Portland, OR (US); Punyashloka Debashis, Hillsboro, OR (US); Dominique A. Adams, Portland, OR (US); I-Cheng Tung, Hillsboro, OR (US); Arnab Sen Gupta, Hillsboro, OR (US); Gauri Auluck, Hillsboro, OR (US); Scott B. Clendenning, Portland, OR (US); Pratyush P. Buragohain, Hillsboro, OR (US)

(73) Assignee: Intel Corporation, Santa Clara, CA (US)

(21) Appl. No.: 18/341,467

(22) Filed: Jun. 26, 2023

(51) Int. Cl. H01L 29/423; H01L 29/06; H01L 29/66; H01L 29/786

(52) U.S. Cl. CPC H01L 29/42392; H01L 29/06; H01L 29/66439; H01L 29/78696

(57) ABSTRACT

A transistor device may be formed with a doped perovskite material as a channel region. The doped perovskite material may be formed via an epitaxial growth process from a seed layer, and the channel regions of the transistor device may be formed from lateral overgrowth from the epitaxial growth process.

### BACKGROUND

Perovskite materials (e.g., perovskite stannate materials) have shown promise for being used as channel materials with field effect transistors (FETs) as they have high electron mobility. Mobility within these materials may be limited by defects within the material, such as threading dislocations at growth interfaces due to epitaxial lattice mismatches.

### BRIEF DESCRIPTION OF THE DRAWINGS

FIG. 1 illustrates an example portion of a fabrication process for perovskite-based FETs, showing epitaxial overgrowth in accordance with embodiments herein.

FIG. 2 illustrates an example fabrication process for a top-gated perovskite-based FET in accordance with embodiments herein.

FIGS. 3A-3B illustrate an example fabrication process for a bottom-gated perovskite-based FET in accordance with embodiments herein.

FIGS. 4A-4E illustrate an example fabrication process for a perovskite-based gate all around (GAA) FET in accordance with embodiments herein.

FIGS. 5A-5E illustrate another example fabrication process for a perovskite-based gate all around (GAA) FET in accordance with embodiments herein.

FIG. 6 is a top view of a wafer and dies that may incorporate any of the embodiments disclosed herein.

FIG. 7 is a cross-sectional side view of an integrated circuit device that may incorporate any of the embodiments disclosed herein.

FIG. 8 is a cross-sectional side view of an integrated circuit device assembly that may include any of the embodiments disclosed herein.

FIG. 9 is a block diagram of an example electrical device that may include any of the embodiments disclosed herein.

### DETAILED DESCRIPTION

Embodiments herein include perovskite-based field effect transistor (FET) devices enabled by epitaxial lateral overgrowth during fabrication. Perovskite materials (e.g., perovskite stannate materials such as BaSnO₃ (also referred to herein as BSO) doped with Lanthanum (La)) have shown promise for being used as channel materials with field effect transistors (FETs) as they have high electron mobility. Mobility within these materials may be limited by defects within the material, such as threading dislocations at growth interfaces due to epitaxial lattice mismatches. These defects may be decreased, however, by epitaxial lateral overgrowth, which can accordingly enable high performance transistors to be fabricated (e.g., perovskite-based transistors). In particular, epitaxial lateral overgrowth allows regions of low-defect doped perovskite materials, such as La—BaSnO₃ or other perovskite semiconductor materials, to be formed, and these low-defect regions may be used as the channel regions in high performance transistor devices.

Lanthanum-doped BaSnO₃ (also referred to herein as LBSO) is known to create threading dislocation at growth interfaces due to epitaxial lattice mismatches. These threading dislocations decrease the mobility of carriers and therefore decrease the amount of current that is able to flow in the transistor device. To create higher performance transistors using LBSO, embodiments herein may use selective area growth and epitaxial lateral overgrowth to deposit areas of LBSO with decreased defect density.

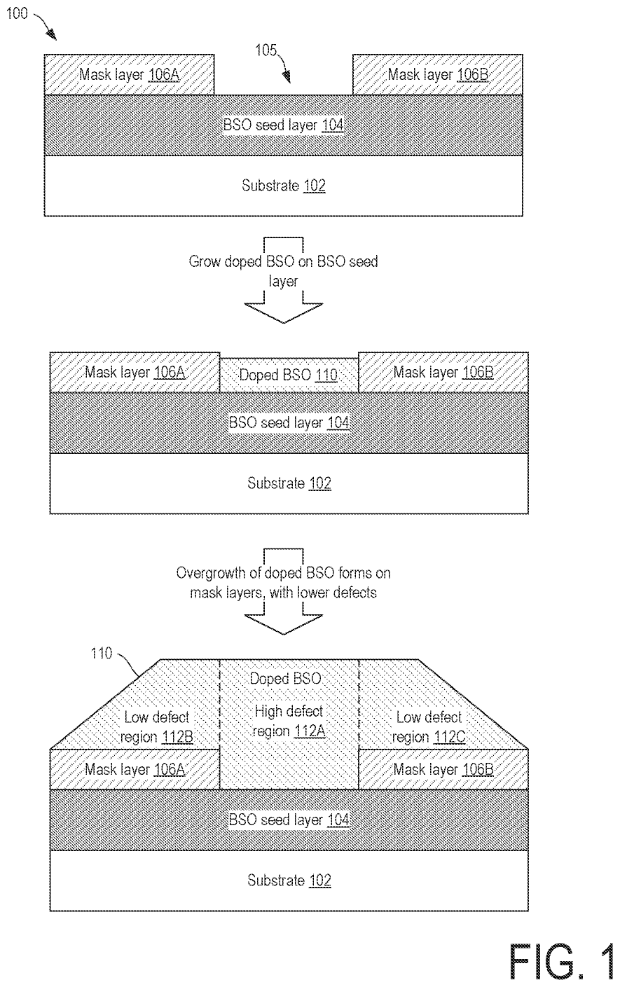

FIG. 1 illustrates an example portion of a fabrication process 100 for perovskite-based FETs, showing epitaxial overgrowth in accordance with embodiments herein. As shown, the perovskite-based FET is formed with a substrate 102 and a seed layer 104 comprising BSO (“BSO seed layer”). The substrate 102 may include one or more of Si, SiGe, Ge, SrTiO3, LaAlO3, YSZ, MgO, LaLuO3, La(LuSc)O3, MgAl2O4, Al2O3, ReScO₃ (where Re may be Dy, Tb, Gd, Eu, Sm, Nd, Pr, Ce, or La). In certain embodiments, the seed layer 104 may include one or more of doped BaSnO₃, undoped BaSnO₃ (which may provide advantages as doping can increase defects), SrSnO₃, or another perovskite such as SrTiO₃, LaAlO₃, BaHfO₃, BaZrO₃, SrZrO₃, SrHfO₃, LaInO₃, LaScO₃, LaLuO₃, La(LuSc)O₃, YAlO₃, and ReScO₃ (where, in some embodiments, Re may be Dy, Tb, Gd, Eu, Sm, Nd, Pr, Ce, or La). The seed layer 104 may be considered as a sacrificial layer in certain embodiments. Thus, it may have the same perovskite structure so layers grown thereon can epitaxially inherit the crystalline structure of the seed layer. A mask layer 106 is then formed on the seed layer 104 with an opening 105 exposing the seed layer 104. The mask may be composed of a material such as SiO2, MgO, HfO2, or a photoresist. A doped BSO layer 110 is then epitaxially grown on the seed layer 104 in the opening 105 as shown. The doped BSO layer may include doped BaSnO3, doped SrSnO3, doped (BaSr)SnO3, doped SrTiO₃, or another doped perovskite material, where the dopants include one or more of La, Nd, Ce, Cs, Y, V, K, and Co, for example.

The doped BSO 110 may be formed using a deposition method that enables epitaxial lateral overgrowth, for example, methods such as MOCVD (metal organic chemical vapor deposition). In some instances, the epitaxial growth in the region 112A over the seed layer may include a relatively high number of defects, e.g., those caused by threading dislocation as described above, whereas the overgrowth regions 112B, 112C over the mask layer 106A, 106B, respectively, may include relatively fewer defects than within the region 112A. The lower defect regions 112B, 112C may accordingly provide higher carrier mobility for FETs that utilize the doped BSO layer 110 as the channel, e.g., as shown in the examples described below.

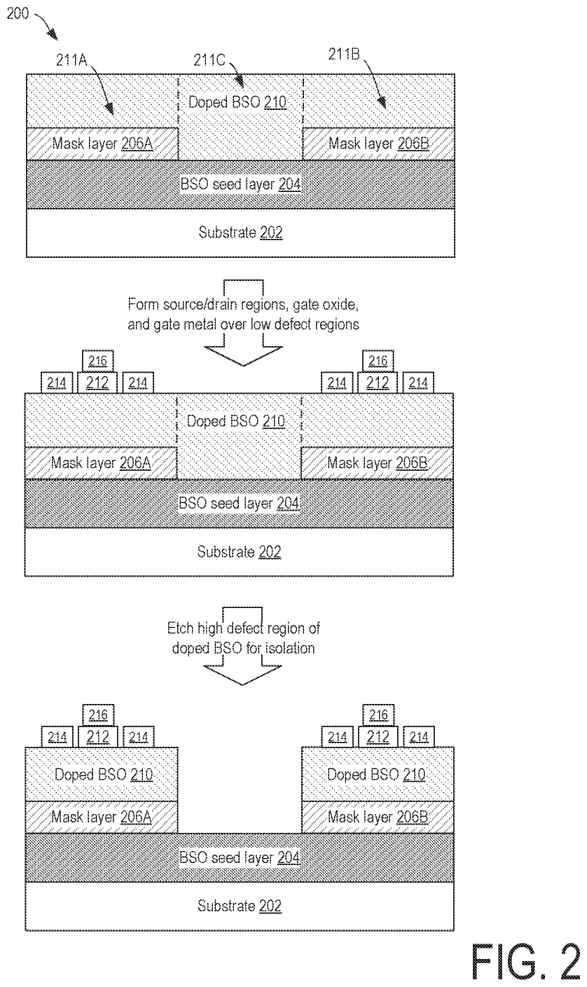

FIG. 2 illustrates an example fabrication process 200 for a top-gated perovskite-based FET in accordance with embodiments herein. The example process shown may include additional, fewer, or different operations than those shown or described below. In some embodiments, one or more of the operations shown in FIG. 2 include multiple operations, sub-operations, etc.

The illustrated process 200 begins with a material stack comprising a substrate 202, BSO seed layer 204 on the substrate 202, a mask layer 206 on the BSO seed layer 204, and a doped BSO layer 210 epitaxially grown on the seed layer 204 and overgrown onto the mask layer 206. The substrate 202 may be implemented in the same or similar manner as the substrate 102, the seed layer 204 may be implemented in the same or similar manner as the seed layer 104, the mask layer 206 may be implemented in the same or similar manner as the mask layer 106, and the doped BSO layer 210 may be implemented in the same or similar manner as the doped BSO layer 110.

Transistor devices can then be formed on the doped BSO layer 110, and in particular, over the low defect regions 211A, 211B of the doped BSO layer 110 over the mask portions 206A, 206B. For instance, in the example shown, gate oxide layers 212 are formed over each of the low defect regions 211A, 211B, and in addition, source/drain regions 214 are formed on either side of the respective gate oxide layer 212, as shown. A gate metal/gate conductor layer 216 is then formed on the gate oxide layer 212. In certain embodiments, the gate oxide layer 212 may include a dielectric material, such as, for example, one or more of HfO₂, doped HfO₂, SiO₂, BaSnO₃, SrSnO₃, SrTiO₃, LaAlO₃, BaHfO₃, BaZrO₃, SrZrO₃, SrHfO₃, LaInO₃, LaScO₃, LaLuO₃, La(LuSc)O₃, ReScO₃ (where Re may be Dy, Tb, Gd, Eu, Sm, Nd, Pr, Ce, or La), and MgO. In some embodiments, the gate oxide layer 212 may be a ferroelectric material to enable a FeFET structure, and in such embodiments the gate oxide material 212 may include one or more of BaTiO3, Ba(Zr,Ti)O₃, (Ba,Ca)TiO₃, (Ba,Sr)TiO₃, (Ba,Ca)(Ti,Zr)O₃, Ba(Hf,Ti)O₃, BiFeO₃, (Bi, La)FeO₃, Bi(Fe,Co))₃, LiNbO₃, KNbO₃, GdFeO₃, (Gd,La)FeO₃, (HfZr)O₂, and doped HfO₂. The source/drain regions 214 and gate metal/gate conductor layer 216 may include one or more of doped BaSnO3, SrRuO3, (Sr,Ba)RuO3, SrIrO3, (La,Sr)MnO3, (La,Sr)CoO3, LaNiO3, LaRuO3, YBa2Cu3O7, SrVO3, SrCoO3, SrMoO3, Ta, Sb, Bi, Al, Mn, Pt, Ru, Ir, Pd, W, Nb, Mo, RuO2, IrO2, MoO2, Ti, Au, Pd.

Next, the high defect region 211C of the doped BSO layer 210 can be etched or otherwise removed to isolate the two transistor devices formed. In other embodiments, the high defect region may be removed prior to the formation of the transistor devices, e.g., prior to formation of one or more of the gate oxide layers 212, source/drain regions 214 and/or gate metal layers 216.

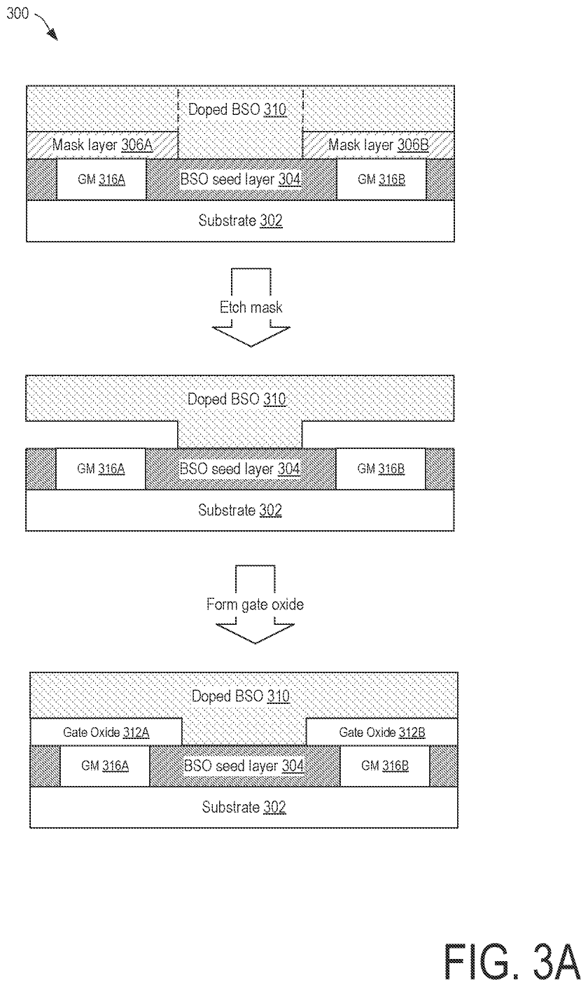

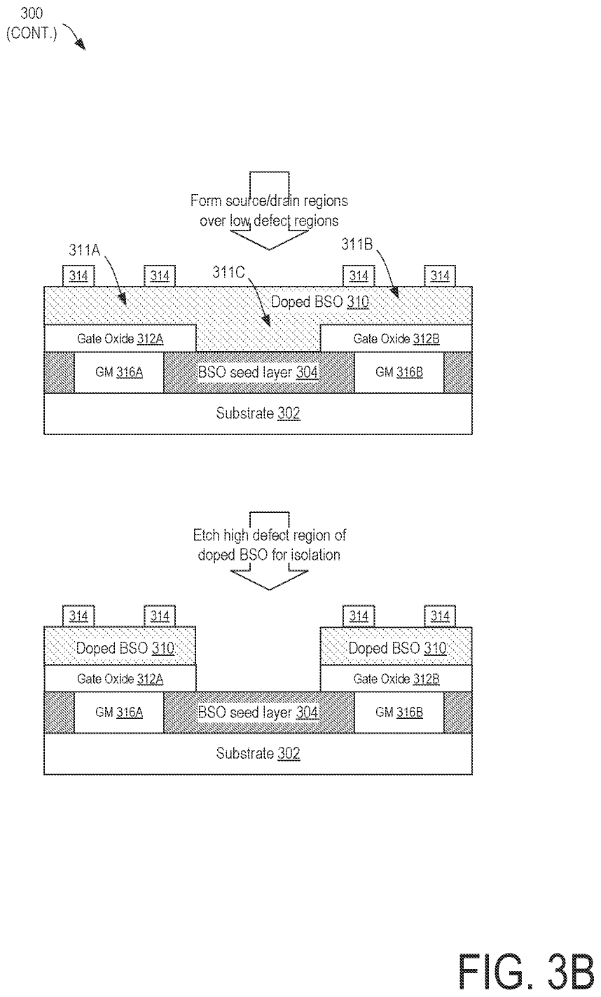

FIGS. 3A-3B illustrate an example fabrication process 300 for a bottom-gated perovskite-based FET in accordance with embodiments herein. The example process shown may include additional, fewer, or different operations than those shown or described below. In some embodiments, one or more of the operations shown in FIGS. 3A-3B include multiple operations, sub-operations, etc.

The illustrated process 300 begins with a material stack comprising a substrate 302, BSO seed layer 304 on the substrate 302, a mask layer 306 on the BSO seed layer 304, and a doped BSO layer 310 epitaxially grown on the seed layer 304 and overgrown onto the mask layer 306. In addition, the example shown includes gate metal layers 316A, 316B formed within the BSO seed layer 304, with the gate metal layer 316A formed under the mask layer portion 316A and the gate metal layer 316B formed under the mask layer portion 316B. The substrate 302 may be implemented in the same or similar manner as the substrate 102, the seed layer 304 may be implemented in the same or similar manner as the seed layer 104, the mask layer 306 may be implemented in the same or similar manner as the mask layer 106, the doped BSO layer 310 may be implemented in the same or similar manner as the doped BSO layer 110, and the gate metal layers 316 may be implemented in the same or similar manner as the gate metal layers 116.

In the example shown, the mask layer 306 is laterally etched from the initial stack and gate oxide layers 312A, 312B are formed in place of the etched mask layer portions. However, in other embodiments, the initial stack may be formed with the gate oxide layers 312A, 312B instead of with a mask layer 306. The gate oxide layers 412 may be implemented in the same or similar manner as previously described. Next, source/drain regions 314 are formed on the doped BSO layer 310, in particular, over the low defect regions 311A, 311B within the doped BSO layer 310. Finally, the high defect region 311C of the doped BSO layer 310 can be etched or otherwise removed to isolate the two transistor devices formed. In other embodiments, the high defect region may be removed prior to the formation of the transistor devices, e.g., prior to formation of the source/drain regions 314.

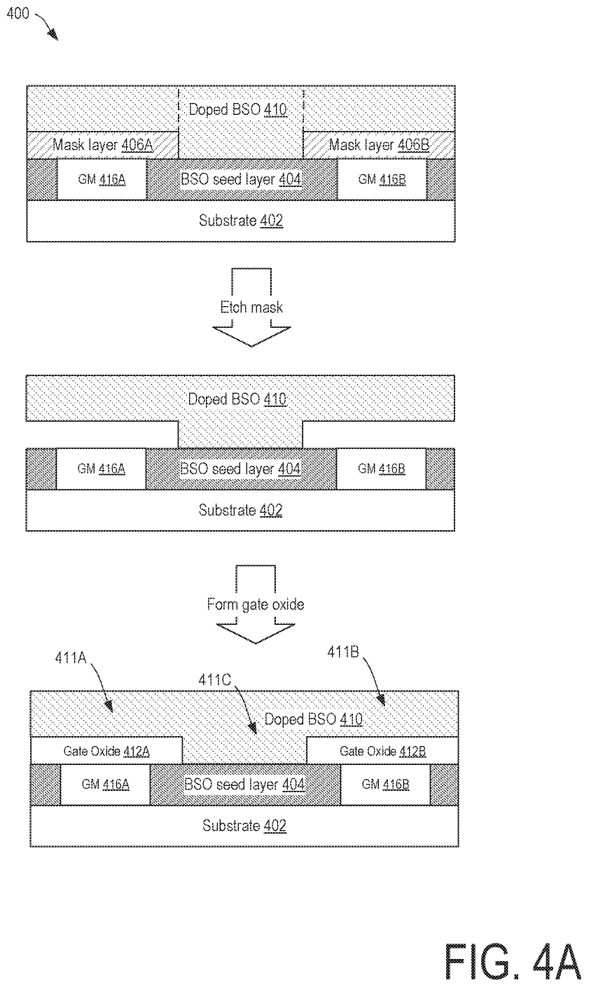

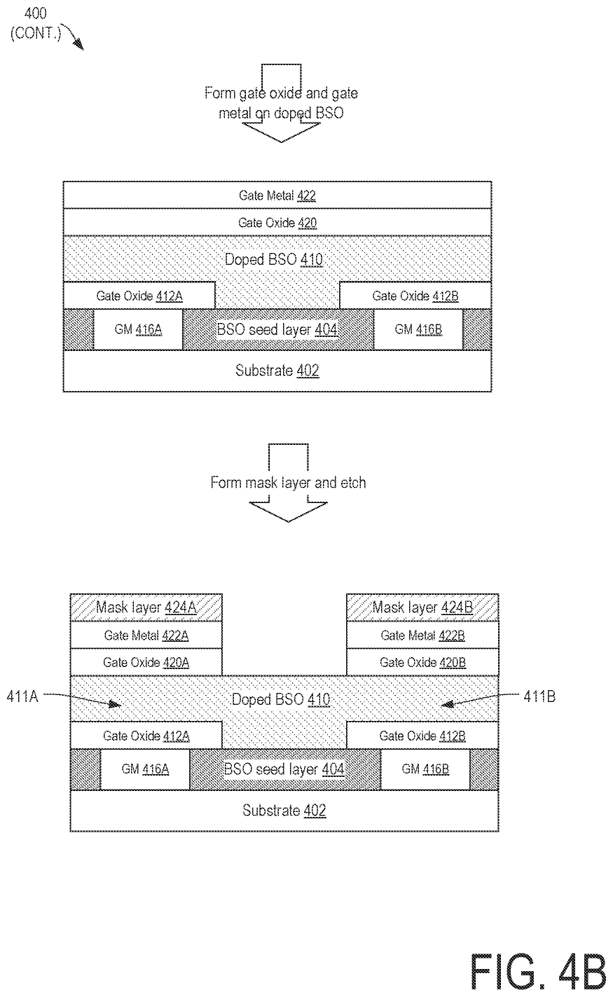

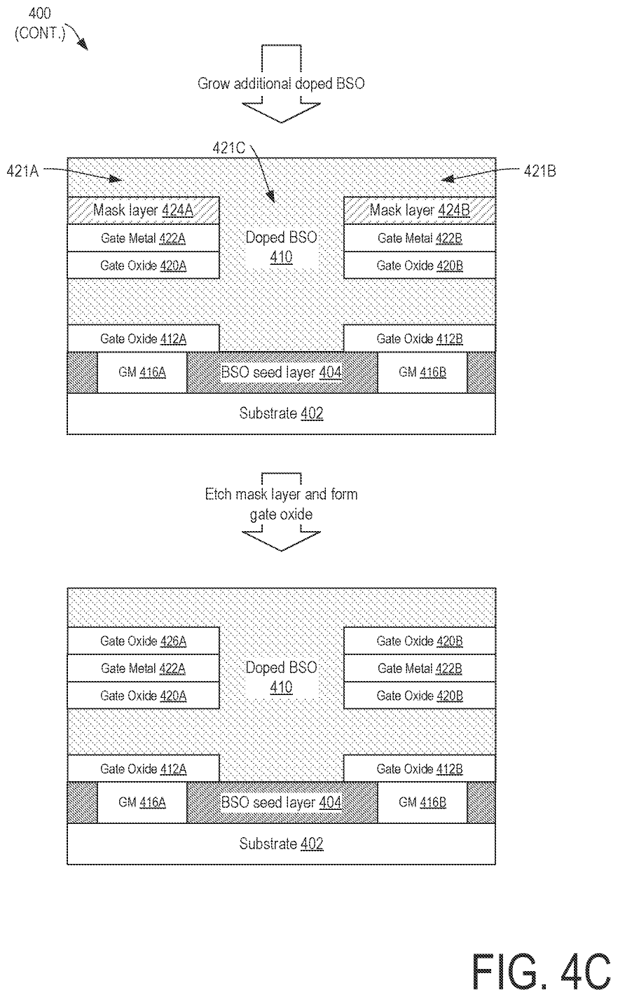

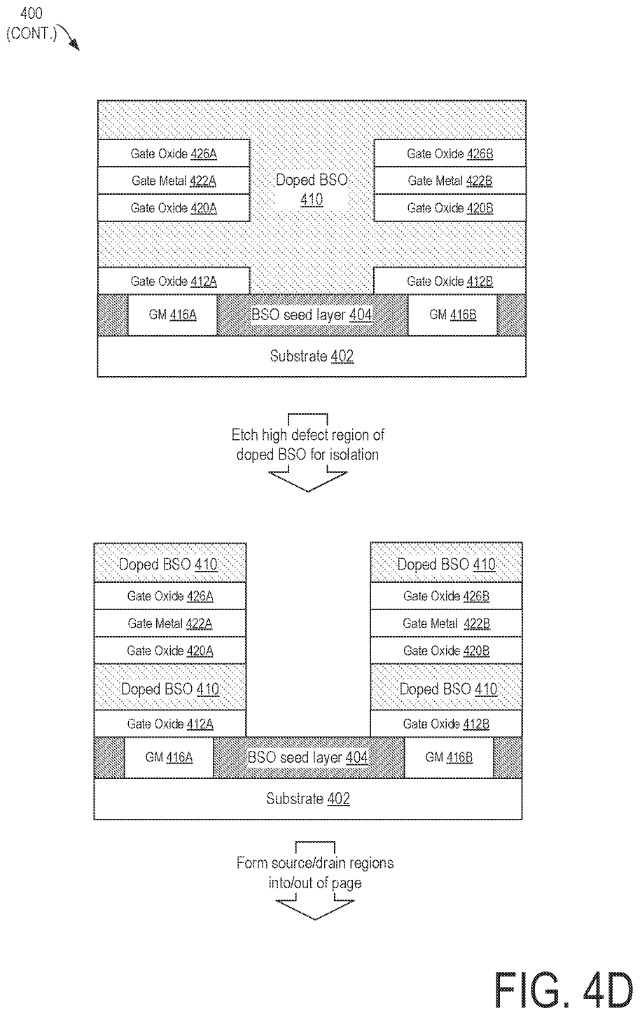

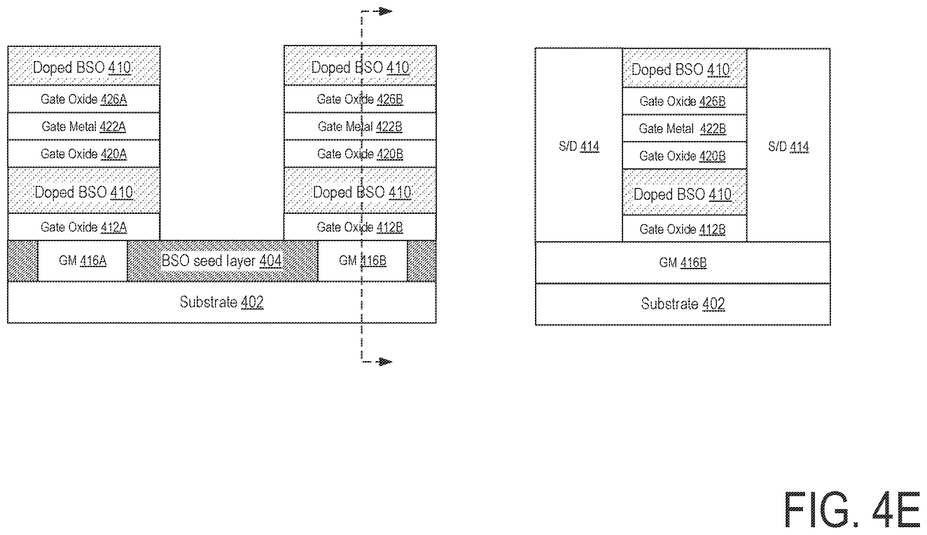

FIGS. 4A-4E illustrate an example fabrication process 400 for a perovskite-based gate all around (GAA) FET in accordance with embodiments herein. The example process shown may include additional, fewer, or different operations than those shown or described below. In some embodiments, one or more of the operations shown in FIGS. 4A-4E include multiple operations, sub-operations, etc.

The illustrated process 400 begins with a material stack comprising a substrate 402, BSO seed layer 404 on the substrate 402, a mask layer 406 on the BSO seed layer 404, and a doped BSO layer 410 epitaxially grown on the seed layer 404 and overgrown onto the mask layer 406. In addition, the example shown includes gate metal layers 416A, 416B formed within the BSO seed layer 404, with the gate metal layer 416A formed under the mask layer portion 416A and the gate metal layer 416B formed under the mask layer portion 416B. The substrate 402 may be implemented in the same or similar manner as the substrates described above, the seed layer 404 may be implemented in the same or similar manner as the seed layers described above, the mask layer 406 may be implemented in the same or similar manner as the mask layers described above, the doped BSO layer 410 may be implemented in the same or similar manner as the doped BSO layers described above, and the gate metal layers 416 may be implemented in the same or similar manner as the gate metal layers described above.

Like the example described previously, the mask layer 406 is laterally etched from the initial stack and gate oxide layers 412A, 412B are formed in place of the etched mask layer portions. However, in other embodiments, the initial stack may be formed with the gate oxide layers 412A, 412B instead of with a mask layer 406. The gate oxide layers 412 may be implemented in the same or similar manner as previously described. Another gate oxide layer 420 is then formed on the doped BSO layer 410, and a gate metal layer 422 is formed on the gate oxide layer 420. Next, mask layers 424A, 424B are formed on the gate metal layer 422 as shown, and the unmasked area of the stack (in the middle of the illustration) is etched down to the doped BSO layer 410. Thereafter, additional doped BSO is grown as shown in FIG. 4C, such that there is overgrowth onto the mask layers 406A, 406B. The middle area 421C of the new growth BSO layer may still contain a relatively high level of defects as described above, whereas the overgrowth areas 421A, 421B may contain a relatively low level of defects as compared with the area 421C.

In the example shown, two channels are formed in the material stack, i.e., the first being between the gate oxide layers 412 and 420, and the second being above the gate metal layers 426. However, in certain embodiments, additional layers may be formed in accordance with the process outlined in the preceding paragraph, i.e., with additional gate oxide and gate metal layers being deposited on the doped BSO layer, a mask being formed on the additional gate metal layer, additional doped BSO growth/overgrowth, and etching/replacing the mask layer with gate oxide, repeated any number of times based on the desired number of doped BSO channels for the stacked transistor device.

Once the desired number of channels have been formed according to the process above, the high defect regions in the doped BSO layer (e.g., 411C, 421C in the middle area of the illustrated stack) are etched or otherwise removed to isolate the two stacked transistor devices. Source/drain regions 414 can then be formed on either side of each stack, into and out of the page with respect to FIG. 4D, as shown in the cross-sectional view of FIG. 4E. The source/drain regions 414 may be implemented in the same or similar manner as the source/drain regions previously described.

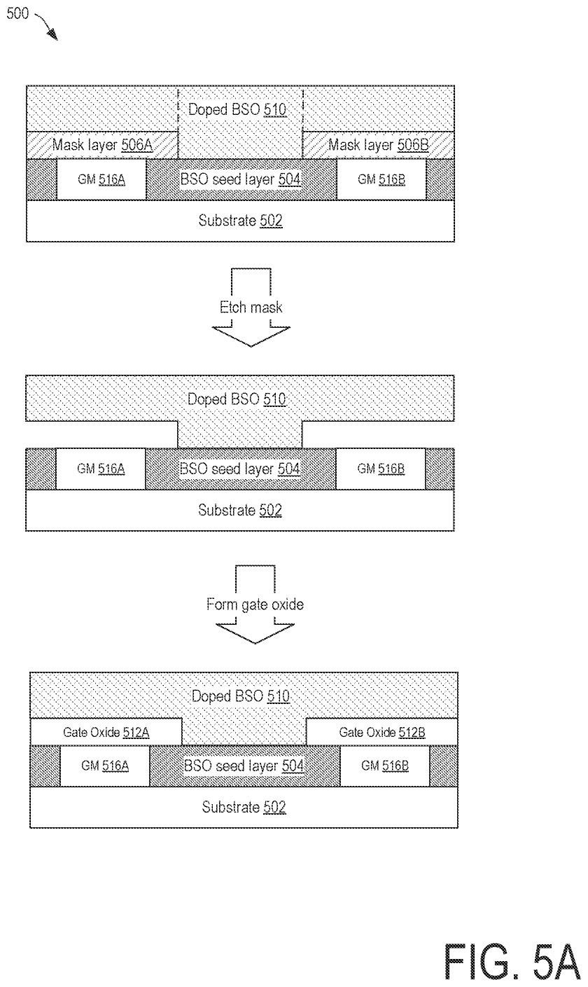

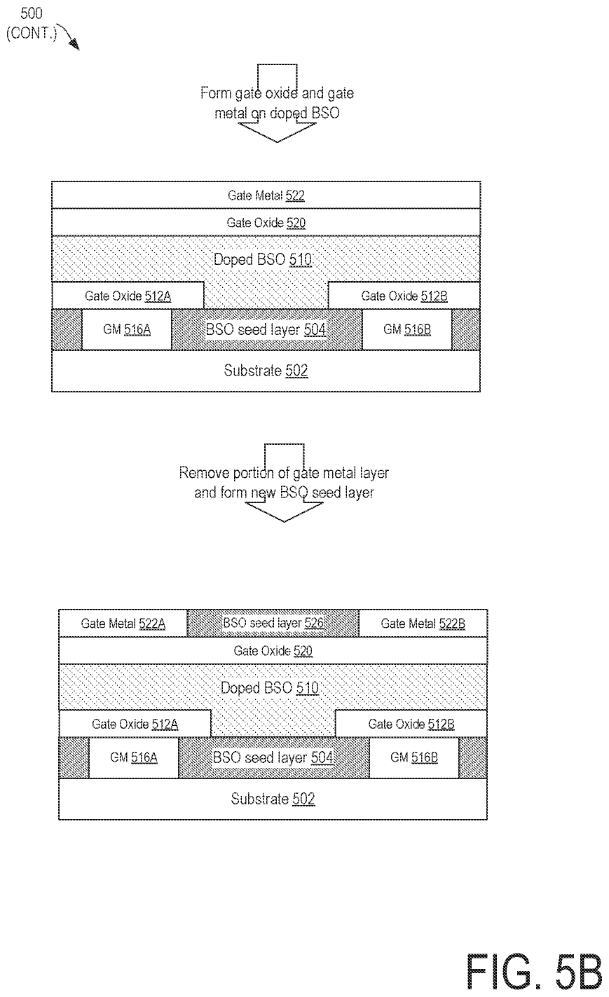

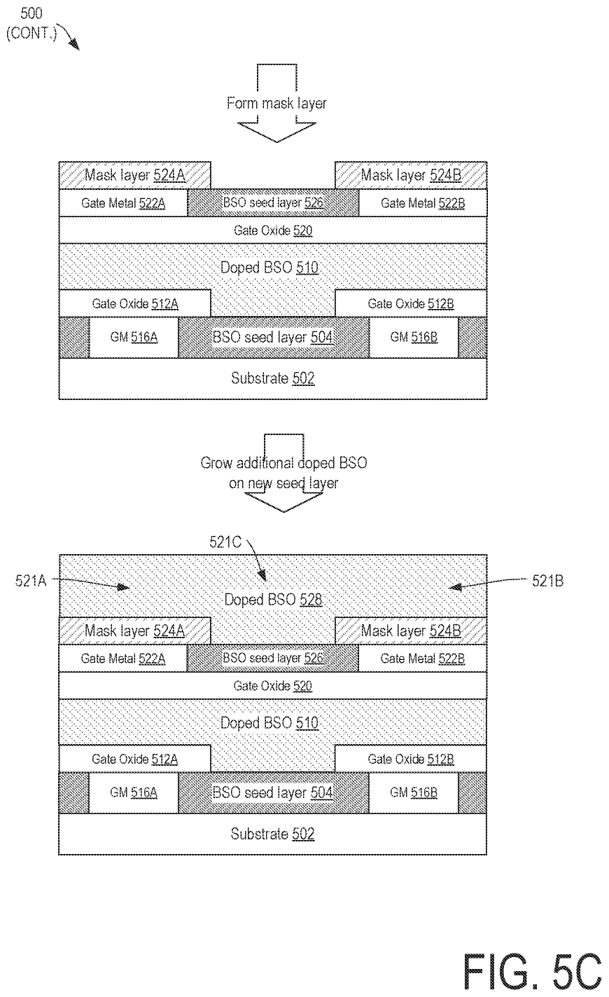

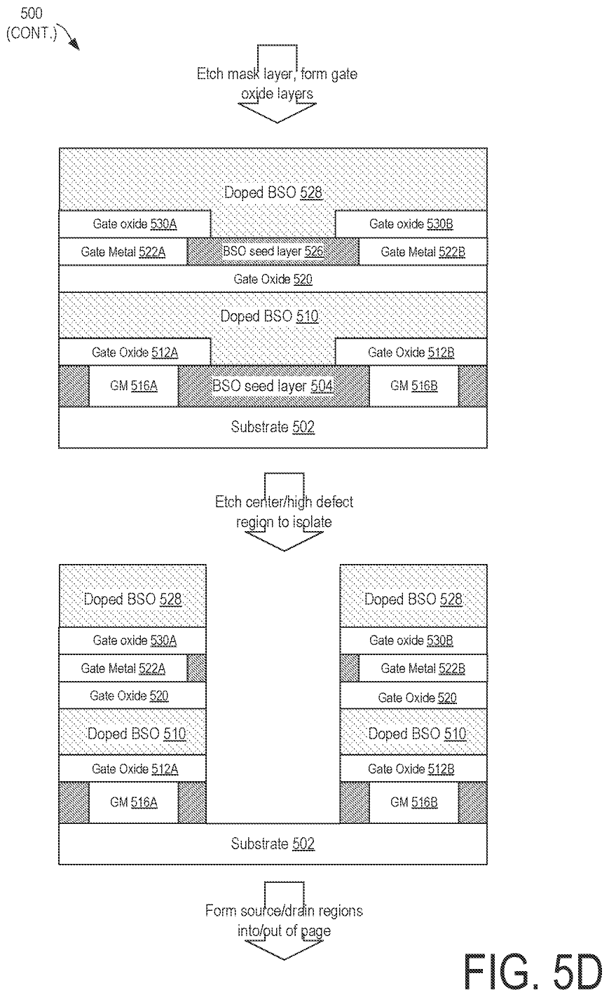

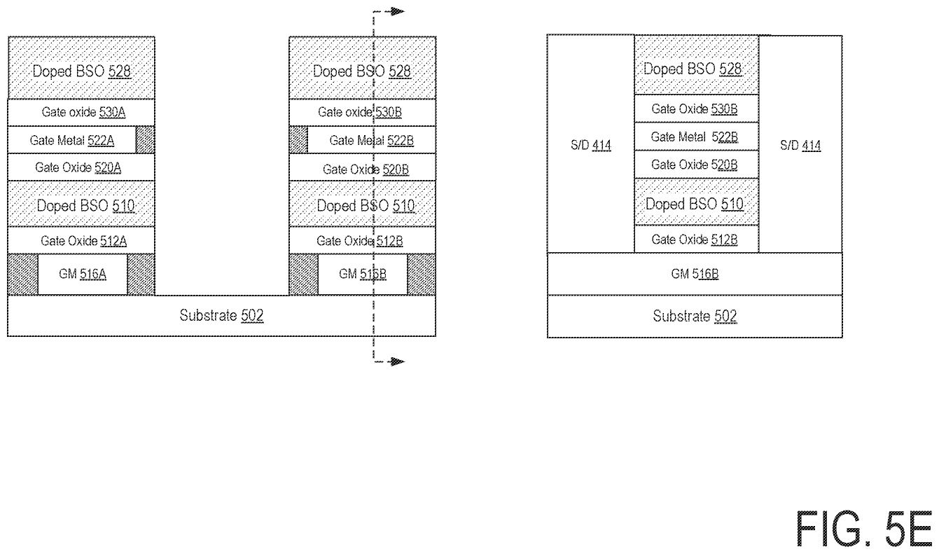

FIGS. 5A-5E illustrate another example fabrication process 500 for a perovskite-based gate all around (GAA) FET in accordance with embodiments herein. The example process shown may include additional, fewer, or different operations than those shown or described below. In some embodiments, one or more of the operations shown in FIGS. 5A-5E include multiple operations, sub-operations, etc.

The illustrated process 500 begins with a material stack comprising a substrate 502, BSO seed layer 504 on the substrate 502, a mask layer 506 on the BSO seed layer 504, and a doped BSO layer 510 epitaxially grown on the seed layer 504 and overgrown onto the mask layer 506. In addition, the example shown includes gate metal layers 516A, 516B formed within the BSO seed layer 504, with the gate metal layer 516A formed under the mask layer portion 516A and the gate metal layer 516B formed under the mask layer portion 516B. The substrate 502 may be implemented in the same or similar manner as the substrates described above, the seed layer 504 may be implemented in the same or similar manner as the seed layers described above, the mask layer 506 may be implemented in the same or similar manner as the mask layers described above, the doped BSO layer 510 may be implemented in the same or similar manner as the doped BSO layers described above, and the gate metal layers 516 may be implemented in the same or similar manner as the gate metal layers described above.

Like the example described previously, the mask layer 506 is laterally etched from the initial stack and gate oxide layers 512A, 512B are formed in place of the etched mask layer portions. However, in other embodiments, the initial stack may be formed with the gate oxide layers 512A, 512B instead of with a mask layer 506. The gate oxide layers 512 may be implemented in the same or similar manner as previously described. Another gate oxide layer 520 is then formed on the doped BSO layer 510, and a gate metal layer 522 is formed on the gate oxide layer 520. Next, a portion of the gate metal layer 522 is removed and a second BSO seed layer 526 is formed in its place (in the middle of the stack shown in FIG. 5B). Then, mask layers 524A, 524B are formed on the gate metal layer 522 and BSO seed layer 526 as shown, and additional doped BSO 528 is grown as shown in FIG. 5C, such that there is overgrowth onto the mask layers 526A, 526B. The middle area 521C of the new growth BSO layer may still contain a relatively high level of defects as described above, whereas the overgrowth areas 521A, 521B may contain a relatively low level of defects as compared with the area 521C. As shown in FIG. 5D, the mask layer 524 is then etched away or otherwise removed, and new gate oxide layers 530A, 530B are formed in place of the mask layer.

In the example shown, two channels are formed in the material stack, i.e., the first being in the doped BSO layer 510 and the second being in the doped BSO layer 528. However, in certain embodiments, additional layers may be formed in accordance with the process outlined in the preceding paragraph, i.e., with additional gate oxide and gate metal layers being deposited on the upper doped BSO layer 528, a BSO seed layer being formed and additional doped BSO growth/overgrowth on the seed layer, repeated any number of times based on the desired number of doped BSO channels for the stacked transistor device.

Once the desired number of channels have been formed according to the process above, the high defect regions in the doped BSO layers (in the middle area of the illustrated stack) are etched or otherwise removed to isolate the two stacked transistor devices. Source/drain regions 514 can then be formed on either side of each stack, into and out of the page with respect to FIG. 5D, as shown in the cross-sectional view of FIG. 5E. The source/drain regions 514 may be implemented in the same or similar manner as the source/drain regions previously described.

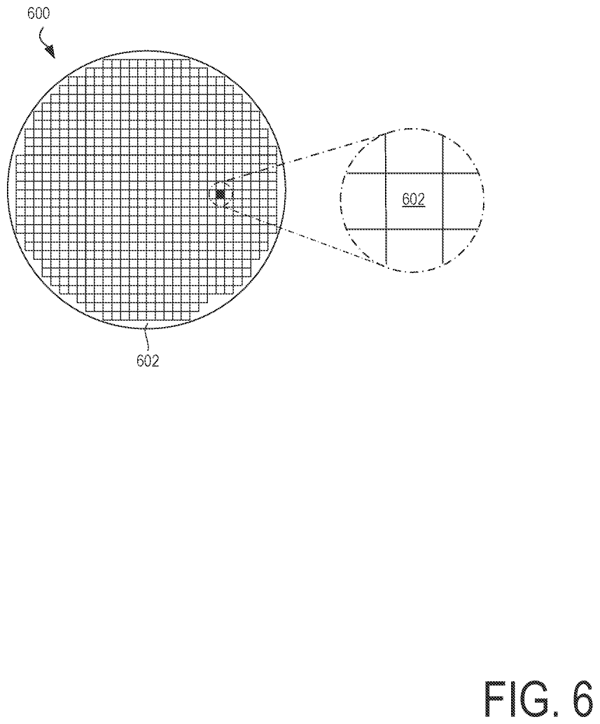

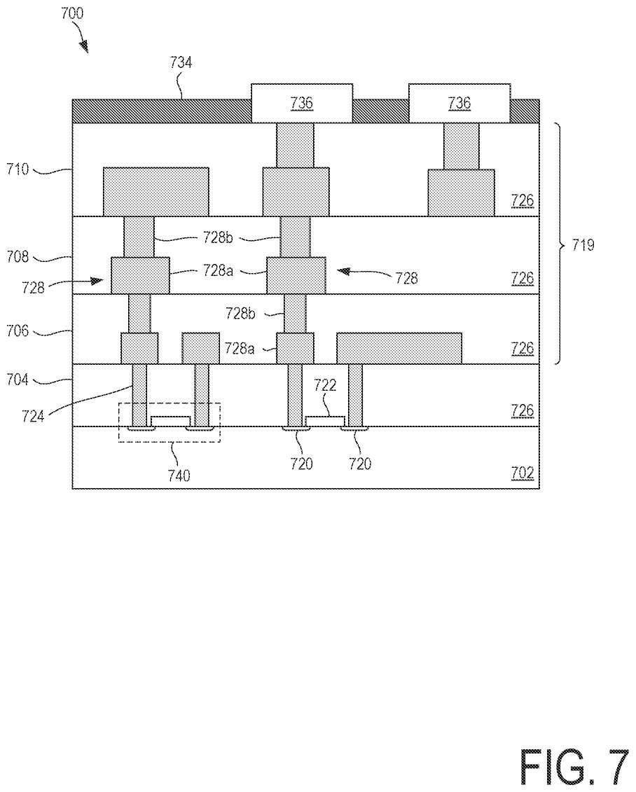

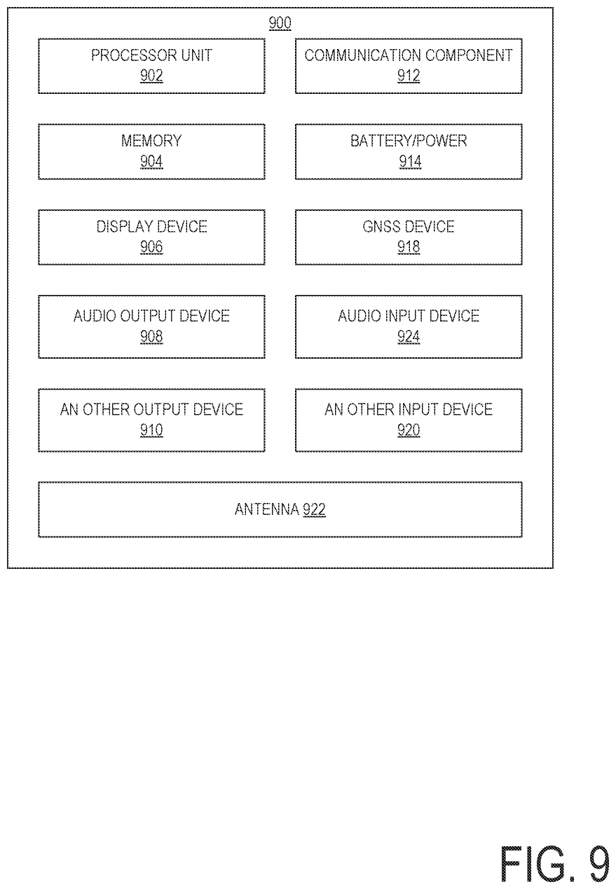

FIG. 6 is a top view of a wafer 600 and dies 602 that may incorporate any of the embodiments disclosed herein. The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 902 of FIG. 9) or other logic that is configured to store information in the memory devices or execute instructions stored in the memory array.

FIG. 7 is a cross-sectional side view of an integrated circuit device 700 that may be included in any of the embodiments disclosed herein. One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 7, a transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. In some embodiments, TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

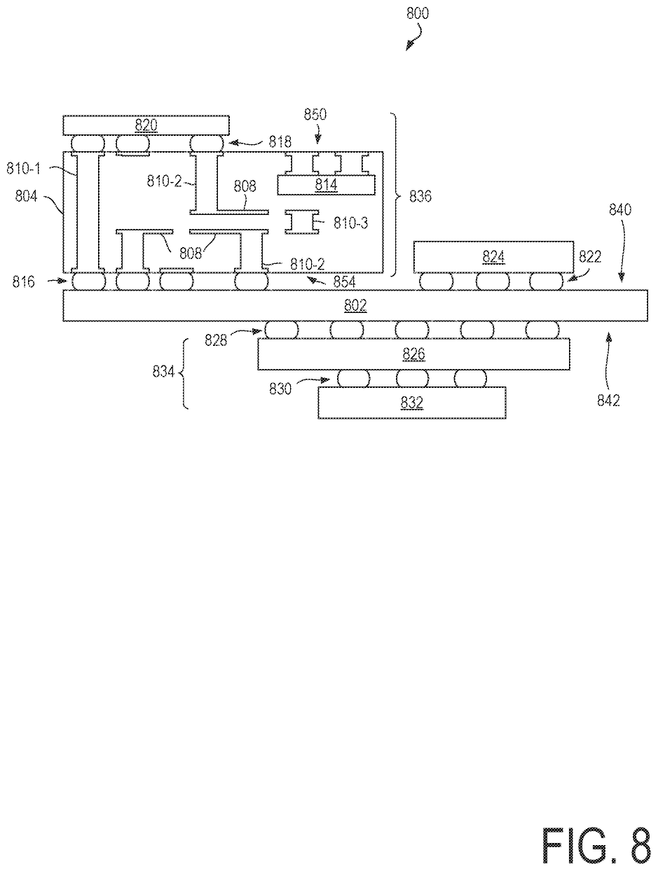

FIG. 8 is a cross-sectional side view of an integrated circuit device assembly 800 that may include any of the embodiments disclosed herein. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpacked integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

FIG. 9 is a block diagram of an example electrical device 900 that may include one or more of the embodiments disclosed herein. For example, any suitable ones of the components of the electrical device 900 may include one or more of the integrated circuit device assemblies 800, integrated circuit components 820, integrated circuit devices 700, or integrated circuit dies 602 disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include an other output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a transistor device comprising: a substrate; a perovskite material seed layer on the substrate; a mask layer on the perovskite material seed layer; a doped perovskite material layer on the mask layer; a dielectric layer on the doped perovskite material layer; a first source/drain region on the doped perovskite material layer and on a first side of the dielectric layer; a second source/drain region on the doped perovskite material layer and on a second side of the dielectric layer opposite the first side; and a conductive metal layer on the dielectric layer.

Example 2 includes the subject matter of Example 1, wherein the perovskite material seed layer comprises Tin and Oxygen.

Example 3 includes the subject matter of Example 1 or 2, wherein the doped perovskite material layer comprises Tin, Oxygen, and at least one of Lanthanum, Neodymium, Cerium, Cesium, Yttrium, Vanadium, Potassium, and Cobalt.

Example 4 includes the subject matter of any one of Examples 1-3, wherein the perovskite material seed layer and the doped perovskite material layer each further comprise at least one of Barium and Strontium.

Example 5 includes the subject matter of Example 1, wherein the perovskite material seed layer comprises Strontium, Titanium, and Oxygen.

Example 6 includes the subject matter of Example 5, wherein the doped perovskite material layer comprises Strontium, Titanium, Oxygen, and at least one of Lanthanum, Neodymium, Cerium, Cesium, Yttrium, Vanadium, Potassium, and Cobalt.

Example 7 includes the subject matter of Example 1, wherein the perovskite material seed layer comprises Scandium and Oxygen.

Example 8 includes the subject matter of Example 7, wherein the doped perovskite material layer comprises Scandium, Oxygen, and at least one of Lanthanum, Neodymium, Cerium, Cesium, Yttrium, Vanadium, Potassium, and Cobalt.

Example 9 includes the subject matter of Example 7 or 8, wherein the perovskite material seed layer and the doped perovskite material layer each further comprise at least one of Rhenium, Dysprosium, Terbium, Gadolinium, Europium, Samarium, and Praseodymium.

Example 10 includes the subject matter of any one of Examples 1-9, wherein the dielectric material is a ferroelectric material.

Example 11 is a transistor device comprising: a substrate; a conductive metal layer on the substrate; a perovskite material seed layer adjacent the conductive metal layer on the substrate; a dielectric layer on the conductive metal layer; a doped perovskite material layer on the dielectric layer; a first source/drain region on the doped perovskite material layer; and a second source/drain region on the doped perovskite material layer.

Example 12 includes the subject matter of Example 11, wherein the perovskite material seed layer comprises Tin and Oxygen.

Example 13 includes the subject matter of Example 11 or 12, wherein the doped perovskite material layer comprises Tin, Oxygen, and at least one of Lanthanum, Neodymium, Cerium, Cesium, Yttrium, Vanadium, Potassium, and Cobalt.

Example 14 includes the subject matter of any one of Examples 11-13, wherein the perovskite material seed layer and the doped perovskite material layer each further comprise at least one of Barium and Strontium.

Example 15 includes the subject matter of Example 11, wherein the perovskite material seed layer comprises Strontium, Titanium, and Oxygen.

Example 16 includes the subject matter of Example 15, wherein the doped perovskite material layer comprises Strontium, Titanium, Oxygen, and at least one of Lanthanum, Neodymium, Cerium, Cesium, Yttrium, Vanadium, Potassium, and Cobalt.

Example 17 includes the subject matter of Example 11, wherein the perovskite material seed layer comprises Scandium and Oxygen.

Example 18 includes the subject matter of Example 17, wherein the doped perovskite material layer comprises Scandium, Oxygen, and at least one of Lanthanum, Neodymium, Cerium, Cesium, Yttrium, Vanadium, Potassium, and Cobalt.

Example 19 includes the subject matter of Example 17 or 18, wherein the perovskite material seed layer and the doped perovskite material layer each further comprise at least one of Rhenium, Dysprosium, Terbium, Gadolinium, Europium, Samarium, and Praseodymium.

Example 20 includes the subject matter of any one of Examples 11-19, wherein the dielectric material is a ferroelectric material.

Example 21 is a transistor device comprising: a substrate; a first conductive metal layer on the substrate; a perovskite material seed layer adjacent the first conductive metal layer on the substrate; a first dielectric layer on the conductive metal layer; a first doped perovskite material layer on the first dielectric layer; a second dielectric layer on the first doped perovskite material layer; a second conductive metal layer on the second dielectric layer; a third dielectric layer on the second conductive metal layer; a second doped perovskite material layer on the third dielectric layer; a first source/drain region adjacent the first doped perovskite material layer and the second doped perovskite material layer; and a second source/drain region adjacent the first doped perovskite material layer and the second doped perovskite material layer.

Example 22 includes the subject matter of Example 21, wherein the perovskite material seed layer comprises Tin and Oxygen.

Example 23 includes the subject matter of Example 21 or 22, wherein the doped perovskite material layer comprises Tin, Oxygen, and at least one of Lanthanum, Neodymium, Cerium, Cesium, Yttrium, Vanadium, Potassium, and Cobalt.

Example 24 includes the subject matter of any one of Examples 21-23, wherein the perovskite material seed layer and the doped perovskite material layer each further comprise at least one of Barium and Strontium.

Example 25 includes the subject matter of Example 21, wherein the perovskite material seed layer comprises Strontium, Titanium, and Oxygen.

Example 26 includes the subject matter of Example 25, wherein the doped perovskite material layer comprises Strontium, Titanium, Oxygen, and at least one of Lanthanum, Neodymium, Cerium, Cesium, Yttrium, Vanadium, Potassium, and Cobalt.

Example 27 includes the subject matter of Example 21, wherein the perovskite material seed layer comprises Scandium and Oxygen.

Example 28 includes the subject matter of Example 27, wherein the doped perovskite material layer comprises Scandium, Oxygen, and at least one of Lanthanum, Neodymium, Cerium, Cesium, Yttrium, Vanadium, Potassium, and Cobalt.

Example 29 includes the subject matter of Example 27 or 28, wherein the perovskite material seed layer and the doped perovskite material layer each further comprise at least one of Rhenium, Dysprosium, Terbium, Gadolinium, Europium, Samarium, and Praseodymium.

Example 30 includes the subject matter of any one of Examples 21-29, wherein the dielectric material is a ferroelectric material.

Example 31 is a method of forming a transistor device, comprising: forming a perovskite material seed layer on a substrate; forming a mask layer on the perovskite material seed layer; forming an opening in the mask layer; forming a doped perovskite material layer on the perovskite material seed layer, wherein forming the doped perovskite material layer causes lateral overgrowth of the doped perovskite material layer onto the mask layer; forming a first dielectric layer on the doped perovskite material layer above a first portion of the mask layer; forming a second dielectric layer on the doped perovskite material layer above a second portion of the mask layer; forming source/drain regions on opposite sides of the first dielectric layer; forming source/drain regions on opposite sides of the second dielectric layer; forming a first conductive metal layer on the first dielectric layer; forming a second conductive metal layer on the second dielectric layer; and removing a portion of the doped perovskite material in a region above the opening in the mask layer.

Example 32 is a method of forming a transistor device, comprising: forming a first conductive metal and a second conductive metal on a substrate; forming a perovskite material seed layer on the substrate adjacent the first conductive metal and the second conductive metal; forming a mask layer on the layer comprising the perovskite material seed layer, the first conductive metal, and the second conductive metal; forming an opening in the mask layer; forming a doped perovskite material layer on the perovskite material seed layer, wherein forming the doped perovskite material layer causes lateral overgrowth of the doped perovskite material layer onto the mask layer; removing the mask layer portions above the first second conductive metal and the second conductive metal; forming a first dielectric layer above the first conductive metal and a second dielectric layer above the second conductive metal; forming a first source/drain region and a second source/drain region on the doped perovskite material layer above the first conductive metal; forming a third source/drain region and a fourth source/drain region on the doped perovskite material layer above the second conductive metal; and removing a portion of the doped perovskite material in a region between the first dielectric layer and the second dielectric layer.

Example 33 is a method of forming a transistor device, comprising: forming a first conductive metal layer and a second conductive metal layer on a substrate; forming a perovskite material seed layer on the substrate adjacent the first conductive metal layer and the second conductive metal layer; forming a first mask layer on the layer comprising the perovskite material seed layer, the first conductive metal layer, and the second conductive metal layer; forming an opening in the first mask layer; forming a doped perovskite material layer on the perovskite material seed layer, wherein forming the doped perovskite material layer causes lateral overgrowth of the doped perovskite material layer onto the first mask layer; removing the first mask layer portions above the first second conductive metal layer and the second conductive metal layer; forming a first dielectric layer above the first conductive metal layer and a second dielectric layer above the second conductive metal layer; forming a third dielectric layer on the doped perovskite material layer; forming a third conductive metal layer on the third dielectric layer; forming a second mask layer on the third conductive metal layer; forming an opening in the second mask layer; removing portions of the third dielectric layer and the third conductive metal layer beneath the opening in the second mask layer to expose the doped perovskite material layer; forming additional doped perovskite material on the doped perovskite material layer, wherein forming the additional doped perovskite material causes lateral overgrowth of the doped perovskite material onto the second mask layer; removing the second mask layer portions above the remaining third conductive metal layer portions; forming a fourth dielectric layer above a first portion of the remaining third conductive metal layer and a fifth dielectric layer above a second portion of the remaining third conductive metal layer; removing a portion of the doped perovskite material in a region between the fourth dielectric layer and the fifth dielectric layer and in a region between the first dielectric layer and the second dielectric layer; and forming a source/drain regions on opposite side of each doped perovskite material layer portion.

Example 34 is a method of forming a transistor device, comprising: forming a first conductive metal layer and a second conductive metal layer on a substrate; forming a first perovskite material seed layer on the substrate adjacent the first conductive metal layer and the second conductive metal layer; forming a first mask layer on the layer comprising the first perovskite material seed layer, the first conductive metal layer, and the second conductive metal layer; forming an opening in the first mask layer; forming a first doped perovskite material layer on the first perovskite material seed layer, wherein forming the first doped perovskite material layer causes lateral overgrowth of the first doped perovskite material layer onto the first mask layer; removing the first mask layer portions above the first second conductive metal layer and the second conductive metal layer; forming a first dielectric layer above the first conductive metal layer and a second dielectric layer above the second conductive metal layer; forming a third dielectric layer on the first doped perovskite material layer; forming a third conductive metal layer on the third dielectric layer; forming an opening in the third conductive metal layer; forming a second perovskite material seed layer on the third dielectric layer between the remaining portions of the third conductive metal layer; forming a second mask layer on the second perovskite material seed layer; forming an opening in the second mask layer; forming a second doped perovskite material layer on the second perovskite material seed layer, wherein forming the second doped perovskite material layer causes lateral overgrowth of the doped perovskite material onto the second mask layer; removing the second mask layer portions above the remaining third conductive metal layer portions; forming a fourth dielectric layer above a first portion of the remaining third conductive metal layer and a fifth dielectric layer above a second portion of the remaining third conductive metal layer; removing a portion of the second doped perovskite material layer in a region between the fourth dielectric layer and the fifth dielectric layer; removing a portion of the first doped perovskite material layer in a region between the first dielectric layer and the second dielectric layer; and forming a source/drain regions on opposite side of each doped perovskite material layer portion.

Example 35 includes the subject matter of any one of Examples 31, 32, 33, or 34, wherein the doped perovskite material layer is formed via an epitaxial growth process.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. A transistor device comprising:
a substrate;
a perovskite material seed layer on the substrate;
a mask layer on the perovskite material seed layer;
a doped perovskite material layer on the mask layer;
a dielectric layer on the doped perovskite material layer;
a first source/drain region on the doped perovskite material layer and on a first side of the dielectric layer;
a second source/drain region on the doped perovskite material layer and on a second side of the dielectric layer opposite the first side; and
a conductive metal layer on the dielectric layer.

2. The device of claim 1, wherein the perovskite material seed layer and the doped perovskite material layer each comprise Tin, Oxygen, and one of Barium and Strontium, and the and the doped perovskite material layer further comprises at least one of Lanthanum, Neodymium, Cerium, Cesium, Yttrium, Vanadium, Potassium, and Cobalt.

3. The device of claim 1, wherein the perovskite material seed layer comprises Strontium, Titanium, and Oxygen, and the doped perovskite material layer comprises Strontium, Titanium, Oxygen, and at least one of Lanthanum, Neodymium, Cerium, Cesium, Yttrium, Vanadium, Potassium, and Cobalt.

4. The device of claim 3, wherein the perovskite material seed layer and the doped perovskite material layer each further comprise at least one of Rhenium, Dysprosium, Terbium, Gadolinium, Europium, Samarium, and Praseodymium.

5. The device of claim 1, wherein the perovskite material seed layer comprises Scandium and Oxygen, and the doped perovskite material layer comprises Scandium, Oxygen, and at least one of Lanthanum, Neodymium, Cerium, Cesium, Yttrium, Vanadium, Potassium, and Cobalt.

6. The device of claim 5, wherein the perovskite material seed layer and the doped perovskite material layer each further comprise at least one of Rhenium, Dysprosium, Terbium, Gadolinium, Europium, Samarium, and Praseodymium.

7. The device of claim 1, wherein the dielectric material is a ferroelectric material.

8. A transistor device comprising:
a substrate;
a conductive metal layer on the substrate;
a perovskite material seed layer adjacent the conductive metal layer on the substrate;
a dielectric layer on the conductive metal layer;
a doped perovskite material layer on the dielectric layer;
a first source/drain region on the doped perovskite material layer; and
a second source/drain region on the doped perovskite material layer.

9. The device of claim 8, wherein the perovskite material seed layer and the doped perovskite material layer each comprise Tin, Oxygen, and one of Barium and Strontium, and the and the doped perovskite material layer further comprises at least one of Lanthanum, Neodymium, Cerium, Cesium, Yttrium, Vanadium, Potassium, and Cobalt.

10. The device of claim 8, wherein the perovskite material seed layer comprises Strontium, Titanium, and Oxygen, and the doped perovskite material layer comprises Strontium, Titanium, Oxygen, and at least one of Lanthanum, Neodymium, Cerium, Cesium, Yttrium, Vanadium, Potassium, and Cobalt.

11. The device of claim 10, wherein the perovskite material seed layer and the doped perovskite material layer each further comprise at least one of Rhenium, Dysprosium, Terbium, Gadolinium, Europium, Samarium, and Praseodymium.

12. The device of claim 8, wherein the perovskite material seed layer comprises Scandium and Oxygen, and the doped perovskite material layer comprises Scandium, Oxygen, and at least one of Lanthanum, Neodymium, Cerium, Cesium, Yttrium, Vanadium, Potassium, and Cobalt.

13. The device of claim 12, wherein the perovskite material seed layer and the doped perovskite material layer each further comprise at least one of Rhenium, Dysprosium, Terbium, Gadolinium, Europium, Samarium, and Praseodymium.

14. The device of claim 8, wherein the dielectric material is a ferroelectric material.

15. A transistor device comprising:
a substrate;
a first conductive metal layer on the substrate;
a perovskite material seed layer adjacent the first conductive metal layer on the substrate;
a first dielectric layer on the conductive metal layer;
a first doped perovskite material layer on the first dielectric layer;
a second dielectric layer on the first doped perovskite material layer;
a second conductive metal layer on the second dielectric layer;
a third dielectric layer on the second conductive metal layer;
a second doped perovskite material layer on the third dielectric layer;
a first source/drain region adjacent the first doped perovskite material layer and the second doped perovskite material layer; and
a second source/drain region adjacent the first doped perovskite material layer and the second doped perovskite material layer.

16. The device of claim 15, wherein the perovskite material seed layer and the doped perovskite material layer each comprise Tin, Oxygen, and one of Barium and Strontium, and the and the doped perovskite material layer further comprises at least one of Lanthanum, Neodymium, Cerium, Cesium, Yttrium, Vanadium, Potassium, and Cobalt.

17. The device of claim 15, wherein the doped perovskite material layer comprises Strontium, Titanium, Oxygen, and at least one of Lanthanum, Neodymium, Cerium, Cesium, Yttrium, Vanadium, Potassium, and Cobalt.

18. The device of claim 17, wherein the perovskite material seed layer and the doped perovskite material layer each further comprise at least one of Rhenium, Dysprosium, Terbium, Gadolinium, Europium, Samarium, and Praseodymium.

19. The device of claim 15, wherein the perovskite material seed layer comprises Scandium and Oxygen, and the doped perovskite material layer comprises Scandium, Oxygen, and at least one of Lanthanum, Neodymium, Cerium, Cesium, Yttrium, Vanadium, Potassium, and Cobalt.

20. The device of claim 19, wherein the perovskite material seed layer and the doped perovskite material layer each further comprise at least one of Rhenium, Dysprosium, Terbium, Gadolinium, Europium, Samarium, and Praseodymium.
